(19) United States
(12) Patent Application Publication
(10) Pub. No.: US 2004/0183168 A1
(43) Pub. Date: Sep. 23, 2004

(54) Lead frame and electronic component using same

(75) Inventors: Tadashi Miyamoto, Hyogo (JP); Yoshihiro Uekawa, Hyogo (JP); Kenichi Asada, Hyogo (JP); Shigeaki Sugawara, Hyogo (JP)

Correspondence Address: MARSHALL, GERSTEIN & BORUN LLP, 6300 SEARS TOWER, 233 S. WACKER DRIVE, CHICAGO, IL, 60606, US

(73) Assignee: HIMEJI TOSHIBA E.P. CORPORATION, Hyogo (JP)

(21) Appl. No.: 10/748,801

(22) Filed: Dec. 30, 2003

(30) Foreign Application Priority Data
Mar. 18, 2003 (JP) 2003-73814

(51) Int. Cl. H01L 23/495

(52) U.S. Cl. 257/666

(57) ABSTRACT

Disclosed are a lead frame and an electronic component using such a lead frame. In order to both assure reliability and reduce costs, the lead frame of the present invention comprises a plate-like disk part on which a chip which is a main body of an electronic component is mounted, and a plate-like lead part formed thinner than the disk part and functioning as an electrical external connecting terminal of the electronic component, wherein the disk part and the lead part are joined together by means of ultrasonic welding.

### BACKGROUND OF THE INVENTION

1. Technical Field of the Invention

The present invention relates to lead frames and to electronic components using such lead frames.

2. Description of the Related Art

Lead frames are used in discrete electronic components.

A typical discrete electronic component is composed of a chip whose main body is made up of semiconductor devices (hereinafter simply called chip). Such a chip is mounted on a lead frame and then wired with lead wires, after which the entire chip is subjected to molding.

Incidentally, a typical lead frame comprises a-plate-like disk part on which a chip is mounted and a lead part which functions as a connecting terminal by means which an electrical connection is made between the discrete electronic component and an external component. The disk part, on which a chip is mounted, is formed relatively thick for holding and heat dissipation of the chip, in other words the disk part functions mainly as a bed mount and as a heat sink. On the other hand, the lead part is formed relatively thin in accordance with the specifications of a socket into which the lead part is inserted. Accordingly, in the lead frame, the disk part is formed thicker than the lead part.

Lead frames of the type described above are generally manufactured by means of rolling. However, this lead frame production method requires that disk and lead parts of different thicknesses should be formed from a plate member that is uniform in thickness, therefore presenting several drawbacks. That is, the number of process steps increases and the cost of production becomes high.

In order to cope with such drawbacks, there is proposed a lead frame production method which is characterized in that a disk part is prepared separately from a lead part and the disk and lead parts are welded together to form a lead frame (see for example Japanese Patent Application Kokai No. (1993)315494).

In accordance with the conventional lead frame production method using a welding technique, disk and lead parts having different thicknesses are formed separately from each other. It is true that the cost of production is reduced as far as such separate preparation of the parts is concerned.

However, in the conventional lead frame production method dependent upon welding, there is the possibility that the merit of reducing the cost of production by separate preparation of a disk part from a lead part is lost unless welding is carried out with high efficiency; on the contrary, the cost of production may increase. In addition, the degree of reliability of welds will matter. In the conventional manufacture method dependent upon welding, various types of welding techniques are employed, such as resistance welding, spot welding, flash butt welding, braze welding et cetera; however, all of these welding techniques are problematic in operating efficiency as well as in weld reliability. For example, in a welding technique (e.g., resistance welding and spot welding) in which portions to be welded are melted completely, there is no pattern to the shape of the welded portions. Accordingly, such a welding technique suffers the problem that welded portions vary widely in mechanical strength. Besides, there is the possibility that balls or the like will be generated. Consequently, the aforesaid conventional lead frame production method dependent upon welding is not in practical use, and it is the case that lead frames are manufactured still by means of rolling.

### SUMMARY OF THE INVENTION

The present invention was made with a view to providing solutions to the above-described problems with the prior art techniques. Accordingly, an object of the present invention is to provide a lead frame capable of both assuring reliability and lowering costs, and an electronic component employing such a lead frame.

In order to achieve the aforesaid object, the present invention discloses a lead frame and an electronic component employing the same. More specifically, the lead frame of the present invention comprises a plate-like disk part on which a chip which is a main body of an electronic component is mounted, and a plate-like lead part formed thinner than the disk part and functioning as an electrical external connecting terminal of the electronic component, wherein the disk part and the lead part are joined together by means of ultrasonic welding (claim 1). In this arrangement, the disk and lead parts are ultrasonic welded together, thereby making it possible to both assure reliability and reduce costs.

It may be arranged such that the disk part has, on the outer periphery thereof, a projected portion and the lead part is ultrasonic welded to the projected portion (claim 2). This arrangement makes it possible to prevent narrowing of the area of a portion of the disk part on which a chip is mounted.

Further, the projected portion may be thinner than a main body of the disk part (claim 3). In this arrangement, the projected portion is thinner than the disk part's main body, so that the projected portion is susceptible to crush. This facilitates ultrasonic welding.

Additionally, it may be arranged such that at least a surface layer portion of the disk part is composed of copper or nickel and at least a surface layer portion of the lead part is composed of nickel or copper (claim 4). Since copper and nickel are of the homogeneous solubility, the joint between the disk part and the lead part is of an FCC structure. Accordingly, the disk and lead parts are joined together particularly strongly.

Furthermore, the present invention discloses a lead frame comprising a plate-like disk part on which a chip which is a main body of an electronic component is mounted, and a plate-like lead part connected to the disk part and functioning as an electrical external connecting terminal of the electronic component, the whole of the lead frame being so formed as to have two portions having different thicknesses, wherein the two portions of different thicknesses are joined together by means of ultrasonic welding (claim 5). In accordance with this arrangement, the two portions differing in thickness from each other are joined together by means of ultrasonic welding, thereby making it possible to reduce costs while at the same time assuring reliability.

Additionally, the present invention discloses a lead frame comprising a plate-like disk part on which a chip which is a main body of an electronic component is mounted, and a plate-like lead part formed thinner than the disk part and functioning as an electrical external connecting terminal of the electronic component, wherein the disk part and the lead part are connected together by welding after caulking (claim 6). In this arrangement, the disk and lead parts are mechanically connected together by caulking and, then, they are electrically connected together sufficiently by welding.

Furthermore, the present invention discloses an electronic component comprising a lead frame as set forth in any one of claims 1, 5, and 6 and a chip which is an electronic component main body, wherein the chip is mounted on a disk part of the lead frame and the chip is electrically connected to a lead part of the lead frame (claim 7). In accordance with this arrangement, the disk and lead parts are joined together by means of ultrasonic welding, thereby making it possible to reduce costs while at the same time assuring reliability. Besides, the disk and lead parts are prepared separately from each other and, therefore, the disk part no longer has a bent portion, thereby making it possible to increase the area thereof. As a result, the heat liberation characteristic of the electronic component is improved. In addition, it becomes possible to select materials having a thermal expansion coefficient approximate to that of the chip, whereby it is possible to reduce metal fatigue in the jointing material (i.e., soldering material) used for chip joint. This achieves further improvement in reliability of the electronic component.

These objects as well as other objects, features and advantages of the present invention will become apparent to those skilled in the art from the following description with reference to the accompanying drawings.

### BRIEF DESCRIPTION OF THE DRAWINGS

FIG. 1 is a perspective view showing an arrangement of a lead frame and an electronic component according to a first embodiment of the present invention;

FIG. 2 is a cross sectional view taken on line II-II of FIG. 1;

FIG. 3, comprised of FIGS. 3A and 3B, shows a disk-parts successively connected strip and a lead-parts successively connected strip for manufacture of a lead frame of FIG. 1, wherein FIG. 3A is a top plan view of the disk-parts successively connected strip and FIG. 3B is a top plan view of the lead-parts successively connected strip;

FIG. 4 is a diagram schematically depicting a process step in which a disk-parts successively connected strip and a lead-parts successively connected strip are joined together by means of ultrasonic welding;

FIG. 5 is a top plan view showing a disk-parts successively connected strip and a lead-parts successively connected strip which are joined together by means of ultrasonic welding;

FIG. 6, comprised of FIGS. 6A-C, shows an arrangement of a lead frame according to a second embodiment of the present invention, wherein FIG. 6A is a top plan view showing a disk-parts successively connected strip before welding, FIG. 6B is a cross sectional view taken on line VIb-VIb of FIG. 6A, and FIG. 6C is a top plan view showing the disk-parts successively connected strip and a lead-parts successively connected strip after welding;

FIG. 7, comprised of FIGS. 7A-C, shows an arrangement of a lead frame according to a modification example of the second embodiment of the present invention, wherein FIG. 7A is a top plan view showing a disk-parts successively connected strip before welding, FIG. 7B is a cross sectional view taken on line VIb-VIb of FIG. 7A, and FIG. 7C is a top plan view showing the disk-parts successively connected strip and a lead-parts successively connected strip after welding; and

FIG. 8, comprised of FIGS. 8A-C, shows an arrangement of a lead frame according to a third embodiment of the present invention, wherein FIG. 8A is a top plan view showing a disk-parts successively connected strip and a lead-parts successively connected strip before caulking, FIG. 8B is a top plan view showing the disk-parts successively connected strip and the lead-parts successively connected strip after caulking, and FIG. 8C is a top plan view showing the disk-parts successively connected strip and the lead-parts successively connected strip after welding.

### DETAILED DESCRIPTION OF THE INVENTION

Hereinafter, preferred embodiments of the present invention will be described with reference to the drawing figures.

First Embodiment

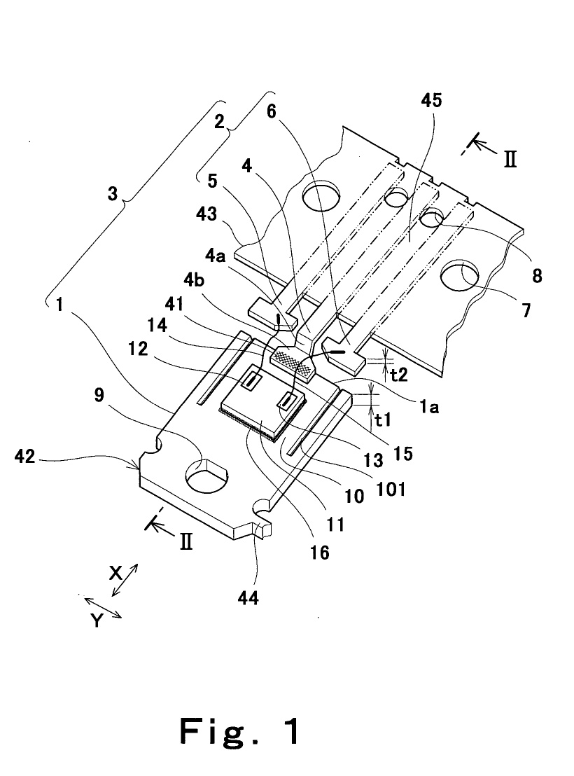

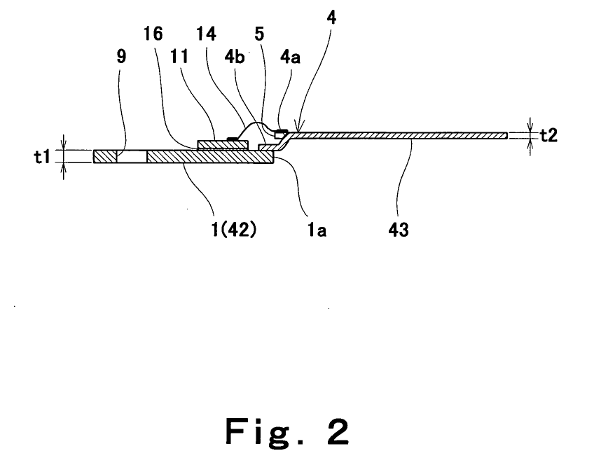

FIG. 1 is a perspective view showing the arrangement of a lead frame and an electronic component according to a first embodiment of the present invention. FIG. 2 is a cross sectional view taken on line II-II of FIG. 1.

Referring to FIGS. 1 and 2, a lead frame 3 of the present embodiment is used in a power transistor as a discrete electronic component. The lead frame 3 has a disk part 1 and a lead part 2. The disk part 1 is shaped like approximately an rectangular flat plate, and has a chip mounting portion 10 and a registration hole 9. The chip mounting portion 10 is so formed in approximately a half of the entire area of the disk part 1 located on the nearer side to the lead part 2 (hereinafter the lead part side) as to be located between a pair of grooves 101. On the other hand, the registration hole 9 is formed centrally in another half of the entire area of the disk part 1 on the far side to the lead part 2. The disk part 1, shown in FIGS. 1 and 2, is in a semi-finished state. A predetermined number of such disk parts 1 are connected together successively by respective bridges 44 to form a single disk-parts successively connected strip 42.

The lead part 2, shown in FIGS. 1 and 2, is also in a semi-finished state. The lead part 2 has a first lead 4 which is located centrally and a second and third leads 5 and 6 between which is located the first lead 4. As indicated by solid line and chain double-dashed line extending therefrom in FIG. 1, each of the leads 4, 5, 6 is shaped such that it has a main body portion of approximately constant width with a head portion having a greater width than that of the main body portion. And, these leads 4, 5, 6 and sets thereof are connected together by respective bridges 45 to form a single lead-parts successively connected strip 43. In this lead-parts successively connected strip 43, the first lead 4 is formed such that it extends beyond the length of the second and third leads 5, 6, and has a tip portion 4b which is stepped down by a step portion 4a. The tip portion 4b of the first lead 4 is shaped like an inverted trapezoid when viewed from above. In addition, registration holes 7, 8 are so formed as to be located between portions of the lead-parts successively connected strip 43 which become the first to third leads 4-6 in a finished state.

Both the disk-parts successively connected strip 42 and the lead-parts successively connected strip 43 are formed uniformly in their thickness. The disk-parts successively connected strip 42 has a thickness of t1. The lead-parts successively connected strip 43 has a thickness of t2 less than the thickness t1 of the disk-parts successively connected strip 42. The registration holes 7, 8, 9 of the disk- and lead-parts successively connected strips 42, 43 are used in the processing of the disk- and lead-parts successively connected strips 42, 43 before and after an ultrasonic welding process step.

The tip portion 4b of the first lead 4 of the lead-parts successively connected strip 43 is joined to a central portion of the upper surface of an end portion 1a on the lead part side of the disk part 1 by means of ultrasonic welding. Reference numeral 41 represents a weld portion made by such ultrasonic welding. As the result of this, the disk part 1 is located lower than the lead part 2 (i.e., the lead-parts successively connected strip 43) by a height corresponding to the sum of the stepped-down length of the step portion 4a and the thickness t2 of the lead-parts successively connected strip 43.

Here, the disk part 1 is composed of copper or copper alloy. Therefore, the disk-parts successively connected strip 42 is composed of copper or copper alloy. Additionally, the first to third leads 4, 5, 6 are composed of nickel plated copper or copper alloy. Therefore, the lead-parts successively connected strip 43 is composed of nickel plated copper or copper alloy.

A chip 11 which constitutes a main body of a power transistor as an electronic component is mounted fixedly on the chip mounting portion 10 of the disk part 1 by a solder 16. Formed on an upper surface of the chip 11 are a pair of pads 12, 13. The pad 12 is connected to the second lead 5 by a metallic lead wire 14, while the pad 13 is connected to the third lead 6 by a metallic lead wire 15. Here, the power transistor as a discrete electronic component is in a semi-finished state. Thereafter, the disk parts 1 and the first, second, and third leads 4, 5, 6 are separated respectively and resin molding is carried out in such a way that end portions of the first, second, and third leads 4, 5, 6 are projected outwardly for a predetermined length, whereby the semi-finished power transistor is now completed.

For the sake of convenience, the direction, in which the first to third leads 4, 5, 6 of the lead frame 3 extend, is called the lengthwise direction (the direction X) of the lead frame 3 and the direction orthogonal to the lengthwise direction when viewed from above is called the crosswise direction (the direction Y) of the lead frame 3.

Hereinafter, an ultrasonic welding technique for jointing together the disk part 1 and the led part 2 by which the present invention is characterized will be described.

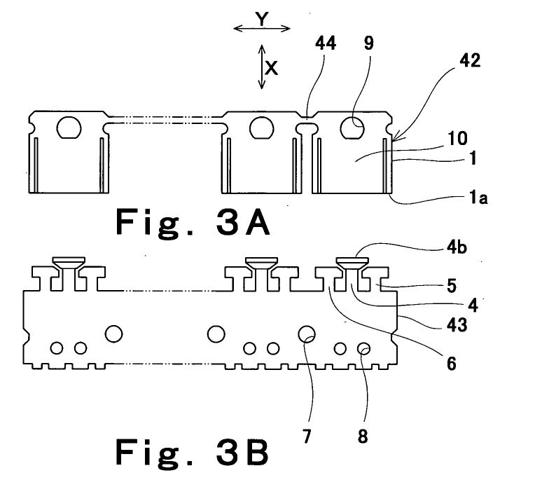

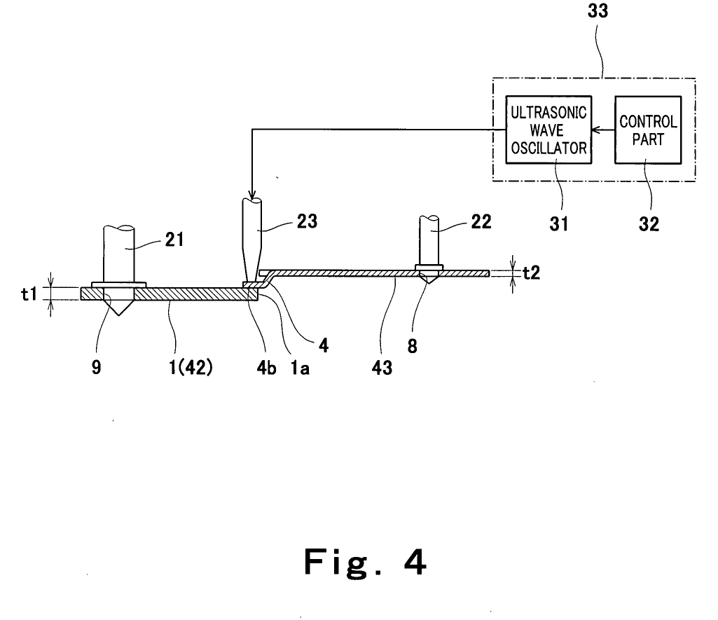

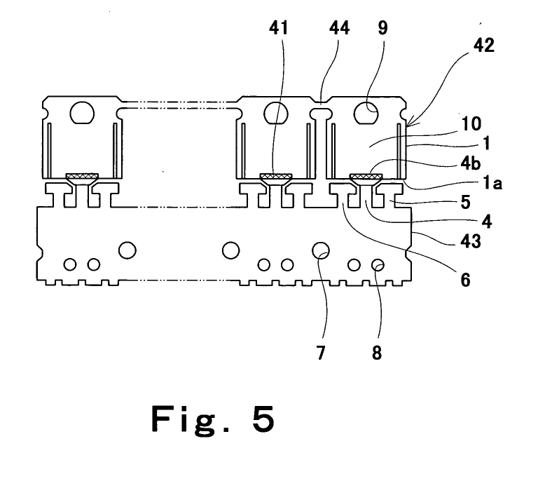

FIG. 3, comprised of FIG. 3A and FIG. 3B, shows a disk-parts successively connected strip and a lead-parts successively connected strip for the manufacture of a lead frame of FIG. 1. More specifically, FIG. 3A is a top plan view showing a disk-parts successively connected strip, and FIG. 3B is a top plan view showing a lead-parts successively connected strip. FIG. 4 is an illustration depicting a process step in which a disk-parts successively connected strip and a lead-parts successively connected strip are joined together by means of ultrasonic welding FIG. 5 is a top plan view showing a disk-parts successively connected strip and a lead-parts successively connected strip which are joined together by means of ultrasonic welding.

As shown in FIG. 3, firstly a disk-parts successively connected strip 42 and a lead-parts successively connected strip 43 are prepared. The disk-parts successively connected strip 42 is composed of a predetermined number of disk parts 1 which are connected together successively in the crosswise direction (the direction Y) by respective bridges 44. The disk-parts successively connected strip 42 is manufactured by pressing a flat plate-like material made of copper or copper alloy by a high speed pressing machine with a progressive die. The lead-parts successively connected strip 43 is prepared by pressing a flat plate-like material of copper or copper alloy which is nickel plated several micrometers by a high speed pressing machine with a progressive die.

On the other hand, the lead-parts successively connected strip 43 is composed of the same number of sets of first, second, and third leads 4, 5, 6 connected together successively as the number of the disk parts 1 of the disk-parts successively connected strip 42.

Referring next to FIG. 4, the disk-parts successively connected strip 42 and the lead-parts successively connected strip 43 are placed one upon the other. At this time, the tip portion 4b of the first lead 4 of the lead-parts successively connected strip 43 is placed on a central portion of the upper surface of the lead part side end portion 1a of the disk part 1 of the disk-parts successively connected strip 42. A portion where the tip portion 4b of the first lead 4 and the lead part side end portion 1a of the disk part 1 is overlapped is called hereinafter a portion to be welded. The disk-parts successively connected strip 42 and the lead-parts successively connected strip 43 are supported, at their lower surfaces, by a receiving member (not shown in the figure). Additionally, a pilot-cum-press pin 21 is inserted in the registration hole 9 of the disk-parts successively connected strip 42 while a pilot-cum-press pin 22 is inserted in the registration hole 8 of the lead-parts successively connected strip 43. The pilot-cum-press pins 21, 22 have diameters corresponding to the registration holes 9, 8 respectively for interfitting therebetween, and are provided with collar portions at their tip portions. Therefore, by insertion of the pilot-cum-press pins 21, 22 into the registration holes 9, 8, both the disk-parts successively connected strip 42 and the lead-parts successively connected strip 43 are positioned firmly in the direction normal to the direction of the thickness as well as in the direction of the thickness.

And, an ultrasonic wave vibrating tool 23 is pressed, at a predetermined pressure, against the to-be-welded portion of the upper surface of the tip portion 4b of the first lead 4. The ultrasonic wave vibrating tool 23 is connected to an ultrasonic wave generator 33. The ultrasonic wave generator 33 is made up of an ultrasonic wave oscillator 31 operable to generate electrical signals at a frequency corresponding to the ultrasonic wave frequency, an operating part (not shown), a control part 32 for controlling the ultrasonic wave oscillator 31 in response to an operation input from the operating part, and the aforesaid ultrasonic wave vibrating tool 23 operable to generate ultrasonic waves by conversion of an electrical signal outputted from the ultrasonic wave oscillator 32 into mechanical vibrations. The ultrasonic wave generator 33 is so constructed as to apply, to the ultrasonic wave vibrating tool 23, pressure variable within a predetermined range.

And, when the ultrasonic wave generator 33 is activated by the operating part in the state shown in FIG. 4, the ultrasonic wave vibrating tool 23 applies ultrasonic wave vibrations and pressure at a given level to the portion to be welded. The portion is ultrasonic welded by heat of friction and applied pressure by the ultrasonic wave vibrations. At the time of the ultrasonic welding, the disk-parts successively connected strip 42 and the lead-parts successively connected strip 43 tend to deviate in the direction X and in the direction Y by the ultrasonic wave vibrations, and to deform in the direction X and in the direction Y by the applied pressure. However, such deviation and deformation is suppressed by the pilot-cum-press pins 21, 22. As a result, the relative positional relationship between the disk-parts successively connected strip 42 and the lead-parts successively connected strip 43 is held, and the position of each part in the disk- and lead-parts successively connected strips 42 and 43 is in conformity with the design values. In other words, ultrasonic welding is carried out in a preferable manner.

FIG. 5 shows a result of the ultrasonic welding process. Referring to FIG. 5, since the portion to be welded will not be melted entirely by the ultrasonic welding, the weld portion 41 is relatively constant in shape, and the variation in mechanical strength of the weld portion 41 is narrowed. In addition, balls or the like will not be generated. Furthermore, welding is carried out with good operating efficiency, and this welding method reduces the total cost of manufacturing lead frames in comparison with the manufacture of lead frames by means of rolling.

Referring also to FIG. 1 which depicts the disk- and lead-parts successively connected strips 42, 43 which are joined together by means of such ultrasonic welding, the chip 11 is fixedly mounted on the chip mounting portion 10 of the disk part 1 by means of soldering. Of the pair of pads 12, 13, the former pad is connected to the second lead 5 by the metallic lead wire 14 while the latter pad is connected to the third lead 6 by the metallic wire 15. Thereafter, the disk parts 11 and the first to third leads 4-6 are separated respectively and the whole of the lead frame is encapsulated by resin, wherein it is arranged such that end portions of the first to third leads 4-6 outwardly project a predetermined length. Hereby, the power transistor is now completed.

As has been described hereinabove, in accordance with the present embodiment, the disk part 1 and the lead part 2 are joined together by the use of ultrasonic welding, thereby enabling separate preparation of the disk part 1 from the lead part 2. Therefore, the reliability of the lead frame 3 is assured while reducing the cost of production thereof.

Additionally, since the disk part 1 is made of copper or copper alloy and the lead part 2 is made of nickel plated copper or copper alloy, this ensures that these parts are joined together strongly. This is because that copper or cooper alloy and nickel are of the homogeneous solubility and the joint between the disk part 1 and the lead part 2 comes to have an FCC structure. Accordingly, it may be arranged such that the disk part 1 is made of nickel plated copper or copper alloy while the lead part 2 is made of copper or copper alloy, which arrangement provides the same effects as above. Of course, both the disk part 1 and the lead part 2 may be made of copper, copper alloy, or nickel plated copper. Also in this case, good joining is achieved.

Furthermore, in accordance with the present embodiment, it is possible to achieve separate preparation of the disk part 1 from the lead part 2. As a result, the disk part 1 no long has a bent portion, thereby making it possible to allow the disk part 1 to have a greater area. Consequently, the heat liberation characteristic of the electronic component is improved. Besides, it becomes possible to select materials having a thermal expansion coefficient approximate to that of the chip 11. This therefore reduces metal fatigue in the jointing material (i.e., soldering material) used for the joining of the chip 11. This achieves further improvement in electronic component reliability. In addition, as a material for the lead frame 3 having a thermal expansion coefficient approximate to that of the chip 11, for example Fe, Fe—Ni alloy, Al, et cetera may be used. Either the whole of the lead frame 3 or its surface layer may be formed by using any one of these materials.

Second Embodiment

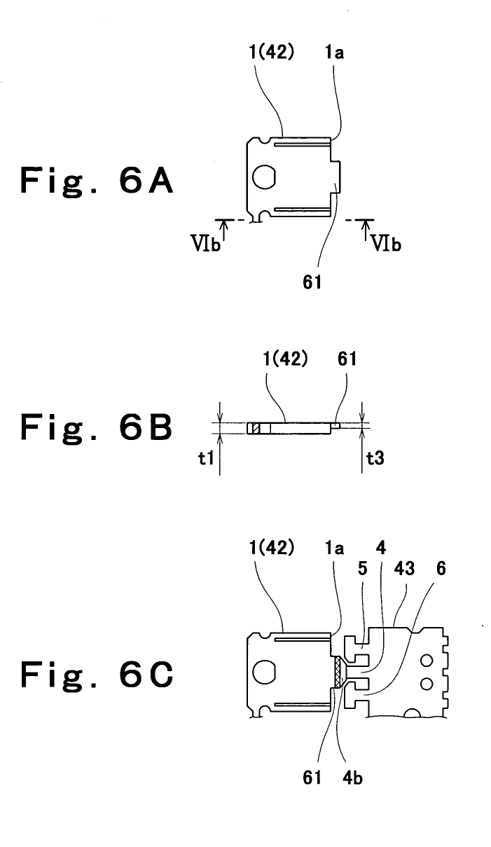

FIG. 6, comprised of FIGS. 6A-C, is an illustration showing an arrangement of a lead frame according to a second embodiment of the present invention. FIG. 6A is a top plan view showing a disk-parts successively connected strip before welding. FIG. 6B is a cross sectional view taken on line VIb-VIb of FIG. 6A. FIG. 6C is a top plan view showing the disk-parts successively connected strip and a lead-parts successively connected strip after welding.

As shown in FIGS. 6A and 6B, a projected portion 61 having a rectangular shape in plan is formed longitudinally centrally in a lead part side end surface of the disk part 1. The upper surface of the projected portion 61 is in a coplanar relationship with the upper surface of the disk part 1, and has a thickness t3 less than the thickness t1 of the disk part 1. And, as shown in FIG. 6C, the tip portion 4b of the first lead 4 is joined to the upper surface of the projected portion 61 by means of ultrasonic welding. Other arrangements are the same as the first embodiment.

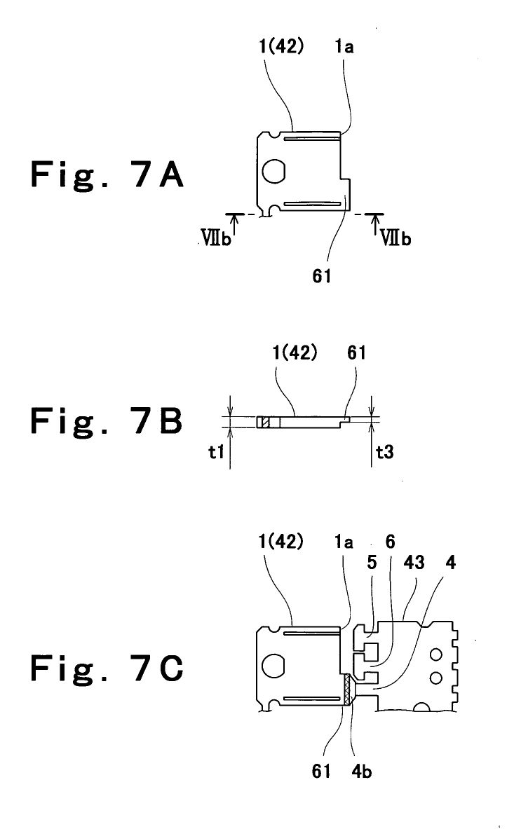

FIG. 7, comprised of FIGS. 7A-C, is an illustration showing an arrangement of a modification example of the lead frame of the second embodiment of the present invention. FIG. 7A is a top plan view showing a disk-parts successively connected strip before welding. FIG. 7B is a cross sectional view taken on line VIIb-VIIb of FIG. 7A. FIG. 7C is a top plan view showing the disk-parts successively connected strip and a lead-parts successively connected strip after welding.

As can be seen from FIGS. 7A and 7B, the projected portion 61 of the modification example of the present embodiment is formed at a longitudinal end portion of the lead part side end surface of the disk part 1. The upper surface of the projected portion 61 is in a coplanar relationship with the upper surface of the disk part 1, and has a thickness t3 less than the thickness t1 of the disk part 1. In this modification example, with the change in formation position of the projected portion 61, the first and third leads 4, 6 are counterchanged in place, as shown in FIG. 7C. And, the tip portion 4b of the first lead 4 is joined to the upper surface of the projected portion 61 by means of ultrasonic welding. Other arrangements are the same as the first embodiment.

Such arrangement prevents the area of the chip mounting portion 10 from becoming narrow by the weld portion. In addition, since the thickness t3 of the projected portion 61 is less than the thickness t1 of the disk part 1, this allows the projected portion 61 to be broken easily, thereby facilitating the process of ultrasonic welding. Here, the best dimensional arrangement is that the thickness t3 of the projected portion 61 equals the thickness of the first lead 4. In such arrangement, ultrasonic welding can be performed in an easiest manner.

Third Embodiment

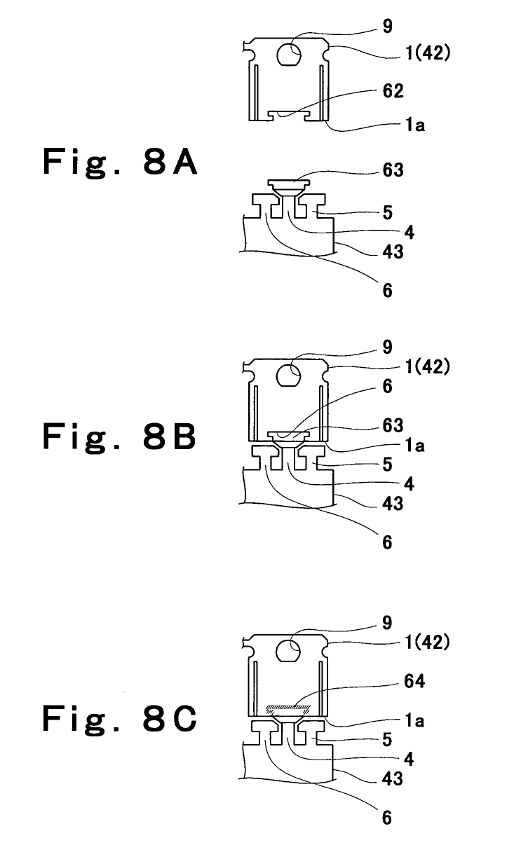

FIG. 8, comprised of FIGS. 8A-C, shows an arrangement of a lead frame according to a third embodiment of the present invention. FIG. 8A is a top plan view showing a disk- and a lead-parts successively connected strip before caulking. FIG. 8B is a top plan view showing the disk- and lead-parts successively connected strips after caulking. FIG. 8C is a top plan view showing the disk- and lead-parts successively connected strips after welding.

Referring now to FIG. 8C, the lead frame of the present invention is formed by first joining together the disk part 1 and the first lead 4 by means of caulking and then welding the joint between the disk part 1 and the first lead 4.

As shown in FIG. 8A which is an illustration of the disk part 1 before undergoing caulking, a narrow notch portion 62 which is wide at the forefront side (inner side) and narrow at the base end side (entrance side) is formed centrally in the lead part side end portion 1a of the disk part 1. On the other hand, a projected portion 63 having a shape interfittable to the notch portion 62 is formed in a tip portion of the first lead 4. The notch portion 62 and the projected portion 63 are not limited in shape to those shown in FIG. 8A, in other words, they may be formed into any shape as long as they are interfitted without the occurrence of slip.

And, as shown in FIG. 8B, the projected portion 63 of the first lead 4 is engagedly inserted into the notch portion 62 of the disk part 1 and a part of the projected portion 63 is crushed so that the projected portion 63 is caulked in the disk part 1. In such a caulked state, the projected portion 63 of the first lead 4 and the disk part 1 are mechanically connected together at the caulked portion; however, electrical connection between them is insufficient.

To cope with such insufficiency of electrical connection strength between the projected portion 63 and the disk part 1, the caulked portion is welded by means of arc welding. Reference numeral 64 denotes a weld portion. Hereby, a surface layer portion of the caulked portion is melted, thereby establishing satisfactory electrical connection between the projected portion 63 of the first lead 4 and the disk part 1. The use of such arc welding ensures that the surface layer portion of the caulked portion is welded with ease. Of course, other welding techniques may be used.

In accordance with the present embodiment, it is possible to provide a reliable and inexpensive lead frame.

In each of the second and third embodiments, the description has been made only in terms of lead frames. However, a desired electronic component can be obtained by mounting a desired chip on such a lead frame and performing wiring and molding thereon according to the method as described in the first embodiment.

Furthermore, in each of the first to third embodiments, the description has been made in terms of the case where the disk part and the lead part are connected together. However, the present invention is applicable to cases where parts of different thicknesses other than the disk and lead parts are connected together.

Finally, in each of the first to third embodiments, the description has been made in terms of the case where the present invention is applied to an electronic component composed of a power transistor. However, it should be noted that the present invention is applicable to other types of electronic components.

Numerous modifications and alternative embodiments of the invention will be apparent to those skilled in the art in view of the foregoing description. Accordingly, the description is to be construed as illustrative only, and is provided for the purpose of teaching those skilled in the art the best mode of carrying out the invention. The details of the structure and/or function may be varied substantially without departing from the sprit of the invention and all modifications which come within the scope of the appended claims are reserved.

What is claimed is:

1. A lead frame comprising a plate-like disk part on which a chip which is a main body of an electronic component is mounted, and a plate-like lead part formed thinner than said disk part and functioning as an electrical external connecting terminal of said electronic component,
wherein said disk part and said lead part are joined together by means of ultrasonic welding.

2. The lead frame as set forth in claim 1, wherein said disk part has, on the outer periphery thereof, a projected portion and said lead part is ultrasonic welded to said projected portion.

3. The lead frame as set forth in claim 2, wherein said projected portion is thinner than a main body of said disk part.

4. The lead frame as set forth in claim 3, wherein at least a surface layer portion of said disk part is composed of copper or nickel and at least a surface layer portion of said lead part is composed of nickel or copper.

5. A lead frame comprising a plate-like disk part on which a chip which is a main body of an electronic component is mounted, and a plate-like lead part connected to said disk part and functioning as an electrical external connecting terminal of said electronic component, the whole of said lead frame being so formed as to have two portions having different thicknesses,
wherein said two portions of different thicknesses are joined together by means of ultrasonic welding.

6. A lead frame comprising a plate-like disk part on which a chip which is a main body of an electronic component is mounted, and a plate-like lead part formed thinner than said disk part and functioning as an electrical external connecting terminal of said electronic component,
wherein said disk part and said lead part are connected together by welding after caulking.

7. An electronic component comprising a lead frame as set forth in any one of claims 1, 5, and 6 and a chip which is an electronic component main body, wherein said chip is mounted on a disk part of said lead frame and said chip is electrically connected to a lead part of said lead frame.
